(19) United States
(12) Patent Application Publication
(10) Pub. No.: US 2010/0039831 A1
(43) Pub. Date: Feb. 18, 2010

(54) Heat dissipation system for a heat generating electronic device

(76) Inventors: Yung-Sheng Liu, Taipei City (TW); Sheng-Yu Wu, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/222,683

(22) Filed: Aug. 14, 2008

(51) Int. Cl. H05K 7/20; B60Q 1/00

(52) U.S. Cl. 362/547; 361/694

(57) ABSTRACT

A heat dissipation system includes a thermal transfer member fixedly secured to a heat generating electronic device and defining with the heat generating electronic device a convection chamber and having a first air hole for guiding hot air out of the convection chamber and a second air hole for guiding outside cold air into the convection chamber, and a heat dissipation device bonded to the bottom wall of the thermal transfer member for quick dissipation of waste heat.

### BACKGROUND OF THE INVENTION

1. Field of the Invention

The present invention relates to a heat dissipation technology and more particularly, to a heat dissipation system for quick dissipation of waste heat from a heat generating electronic device.

2. Description of the Related Art

Following fast development of technology, advanced microprocessor-controlled electronic products have been continuously created and have appeared on the market. During the operation of a microprocessor-controlled electronic product, the microprocessor or CPU generates waste heat. To assure high stability, waste heat must be quickly carried away from the microprocessor or CPU. Further, LED lamps are intensively used in different fields to substitute for conventional incandescent lamps for different purposes. During the operation of a LED lamp, waste heat must be quickly carried away, so that the service life of the LED lamp can be maintained.

### SUMMARY OF THE INVENTION

The present invention has been accomplished under the circumstances in view. It is the main object of the present invention to provide a heat dissipation system for a heat generating electronic device that dissipates waste heat from the heat generating electronic device rapidly through a heat exchange process.

To achieve this and other objects of the present invention, the heat dissipation system comprises a heat generating electronic device, a thermal transfer member and a heat dissipation device. The heat generating electronic device comprises two lugs disposed at two opposite lateral sides. The thermal transfer member is made of a metal material having a high efficiency in heat exchange, comprising two lugs disposed at two opposing sides thereof and respectively affixed to the lugs of the heat generating electronic device, a top open chamber sealed by the heat generating electronic device to form a convection chamber, and two air holes cut through a bottom wall thereof and disposed in communication with the convection chamber. The heat dissipation device is bonded to the bottom wall of the thermal transfer member, having open spaces therein. When the temperature of the air in the convection chamber rises during operation of the heat generating electronic device, the air pressure in the convection chamber is relatively changed, causing hot air to go out of the convection chamber through one air hole of the thermal transfer member and outside cold air to go into the inside of the convection chamber through the other air hole.

### BRIEF DESCRIPTION OF THE DRAWINGS

FIG. 1 is an exploded view of a heat dissipation system in accordance with a first embodiment of the present invention.

FIG. 2 is an elevational assembly view of the heat dissipation system in accordance with the first embodiment of the present invention.

FIG. 3 is a sectional side view of the heat dissipation system in accordance with the first embodiment of the present invention.

FIG. 4 is an exploded view of a heat dissipation system in accordance with a second embodiment of the present invention.

FIG. 5 is an elevational assembly view of the heat dissipation system in accordance with the second embodiment of the present invention.

FIG. 6 is a sectional side view of the heat dissipation system in accordance with the second embodiment of the present invention.

FIG. 7 is an exploded view of a heat dissipation system in accordance with a third embodiment of the present invention.

FIG. 8 is an elevational assembly view of the heat dissipation system in accordance with the third embodiment of the present invention.

FIG. 9 is a sectional side view of the heat dissipation system in accordance with the third embodiment of the present invention.

FIG. 10 is an exploded view of a heat dissipation system in accordance with a fourth embodiment of the present invention.

FIG. 11 is an elevational assembly view of the heat dissipation system in accordance with the fourth embodiment of the present invention.

FIG. 12 is a sectional side view of the heat dissipation system in accordance with the fourth embodiment of the present invention.

FIG. 13 corresponds to FIG. 12, showing the gap between the inner thread of the thermal transfer member and the outer thread of the heat conductive cap sealed with a solder paste.

FIG. 14 is a schematic drawing showing the present invention used in a vehicle headlamp.

FIG. 15 is a schematic drawing showing the arrangement of one light source in the vehicle headlamp shown in FIG. 14.

FIG. 16 is a schematic drawing showing the positioning of the heat transfer member in the back side of the light source holder of the vehicle headlamp shown in FIG. 14.

### DETAILED DESCRIPTION OF THE PREFERRED EMBODIMENT

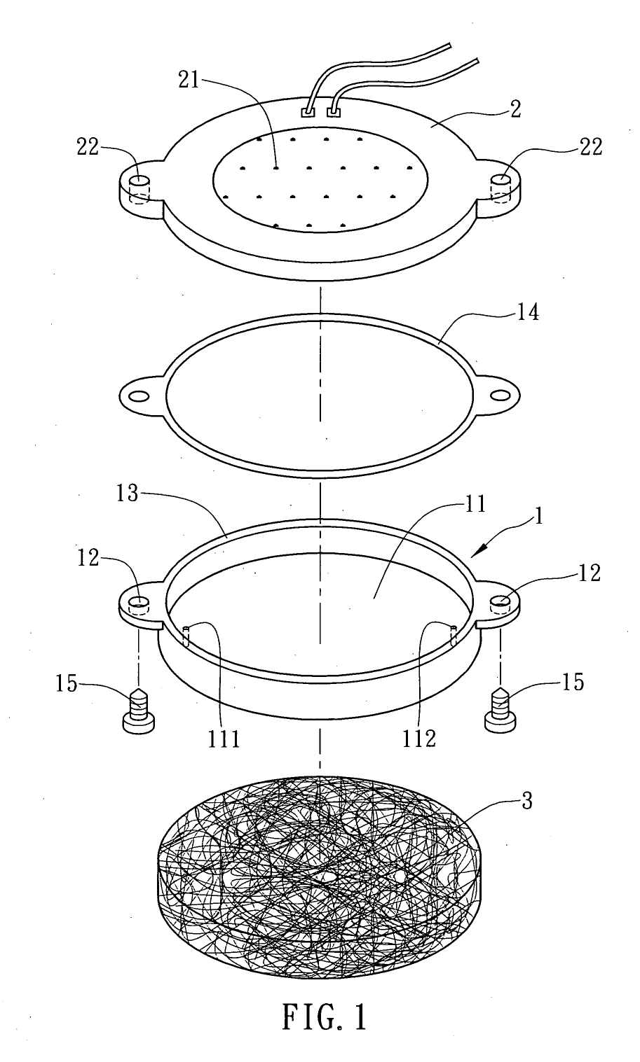

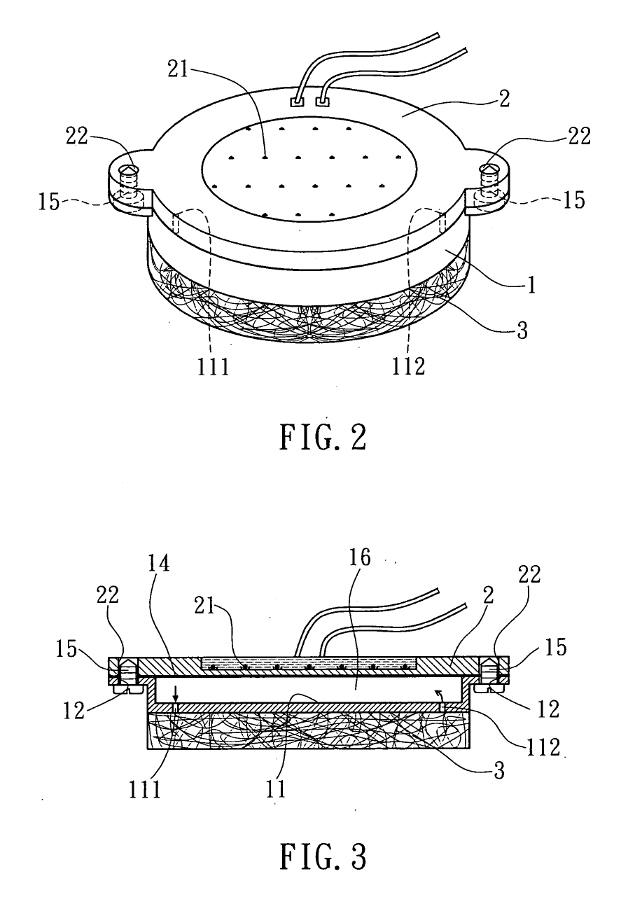

Referring to FIGS. 1˜3, a heat dissipation system in accordance with a first embodiment of the present invention is shown comprised of a thermal transfer member 1, a thermal gasket ring 14, a heat generating electronic device 2, and a heat dissipation device 3.

The thermal transfer member 1 is a hollow rounded metal member defining a top open chamber 11 and having two lugs 12 horizontally outwardly extending from the rim 13 thereof at two opposing sides and two air holes 111 and 112 cut through the bottom wall of the top open chamber 11 at two opposing sides.

The heat generating electronic device 2 can be a LED module or CPU that generates heat during operation. According to this embodiment, the heat generating electronic device 2 is a LED module carrying a number of LED chips 21. The heat generating electronic device 2 has two lugs 22 protruded from the periphery at two opposing sides corresponding to the lugs 12 of the thermal transfer member 1.

The heat dissipation device 3 has open spaces in it for quick dissipation of heat energy.

During installation, the lugs 12 of the thermal transfer member 1 are respectively fastened to the lugs 22 of the heat generating electronic device 2 with fastening members 15 and the thermal gasket ring 14 is sealed between the thermal transfer member 1 and the heat generating electronic device 2, and the heat dissipation device 3 is bonded to the bottom surface of the thermal transfer member 1 opposite to the heat generating electronic device 2 with a thermal adhesive. When assembled, the bottom wall of the heat generating electronic device 2 encloses the top open chamber 11 of the thermal transfer member 1, forming a convection chamber 16. During operation of the heat generating electronic device 2, the temperature of the air in the convection chamber 16 rises, and the air pressure in the convection chamber 16 is relatively changed, causing hot air to go out of the convection chamber 16 through one air hole 111 and outside cold air to go into the inside of the convection chamber 16 through the other air hole 112. During heat exchange, the heat dissipation device 3 dissipates heat energy from the thermal transfer member 1 efficiently, and therefore the temperature of the heat generating electronic device 2 is lowered.

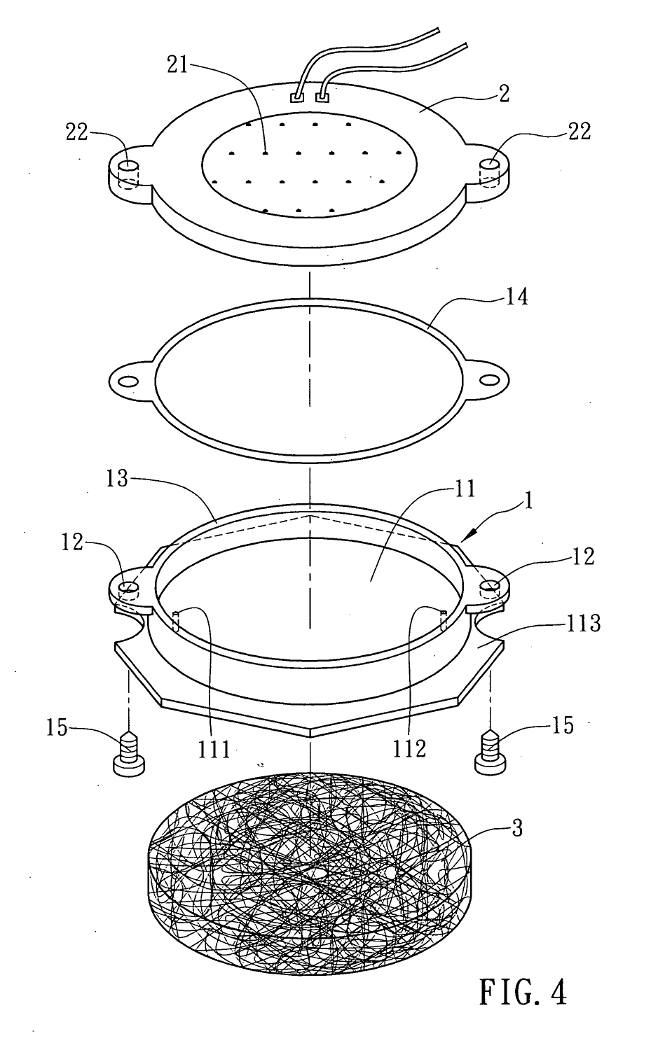

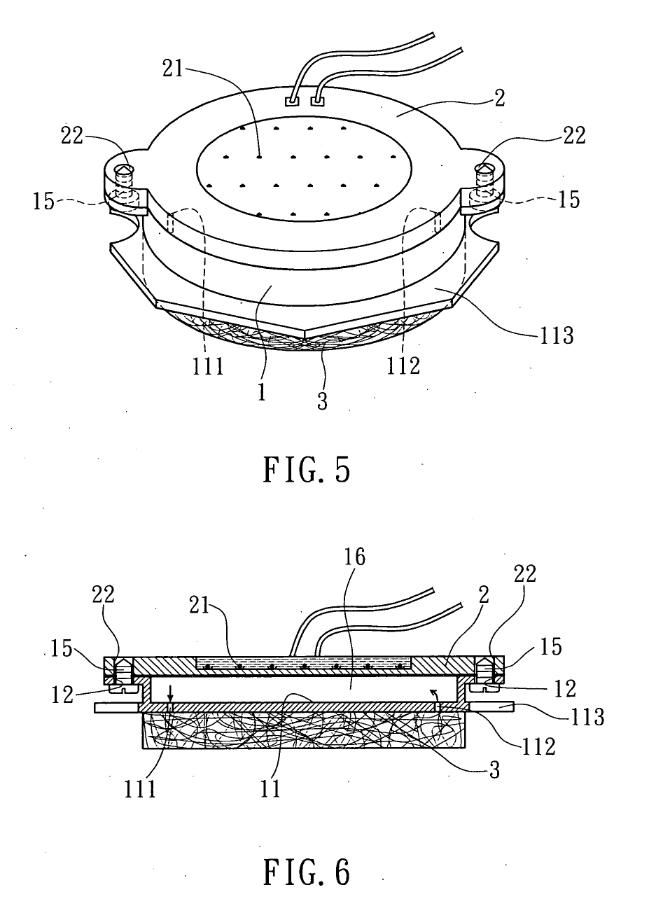

FIGS. 4˜6 show a heat dissipation system in accordance with a second embodiment of the present invention. This second embodiment is substantially similar to the aforesaid first embodiment with the exception that the thermal transfer member 1 further comprises a bottom extension flange 113 outwardly extending from the periphery at the bottom side, increasing the heat dissipation area.

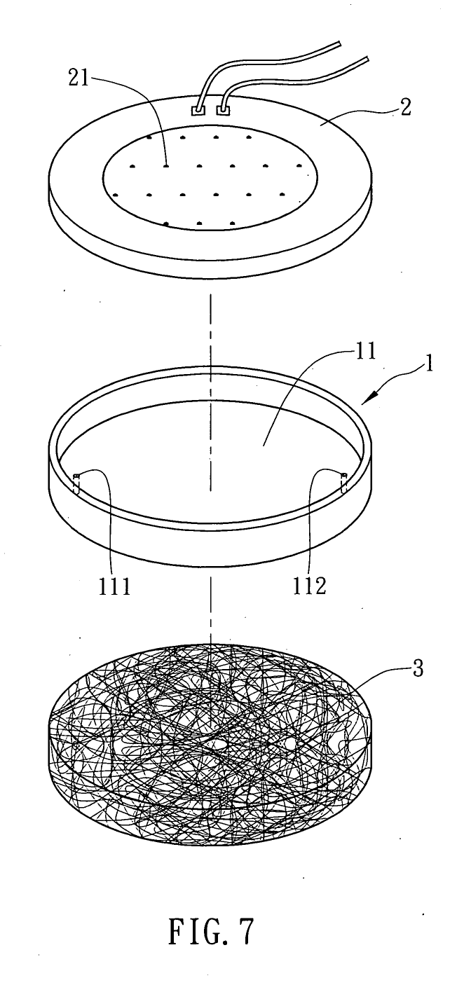

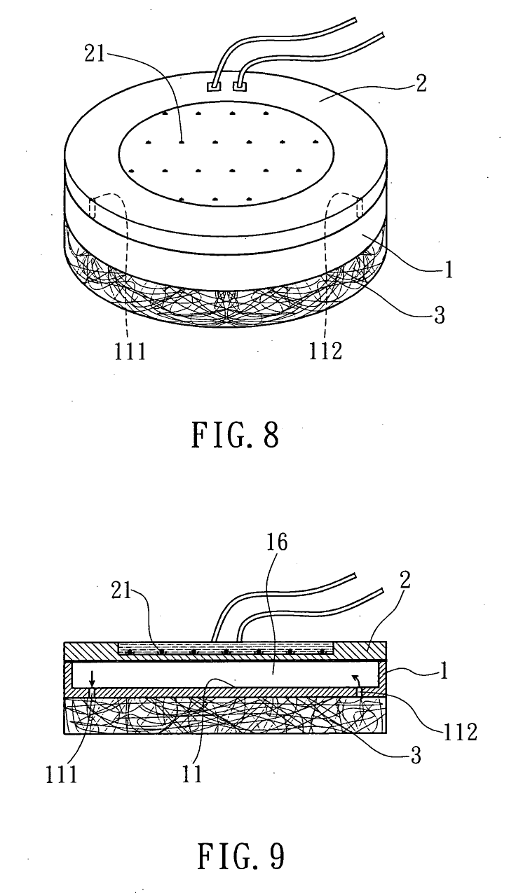

FIGS. 7˜9 show a heat dissipation system in accordance with a third embodiment of the present invention. According to this embodiment, the thermal transfer member 1 is directly bonded to the border area of the bottom wall of the heat generating electronic device 2. The thermal transfer member 1 can be made of a metal material through an extrusion, power metallurgy or powder sintering technique, or made of a ceramic material through a sintering technique.

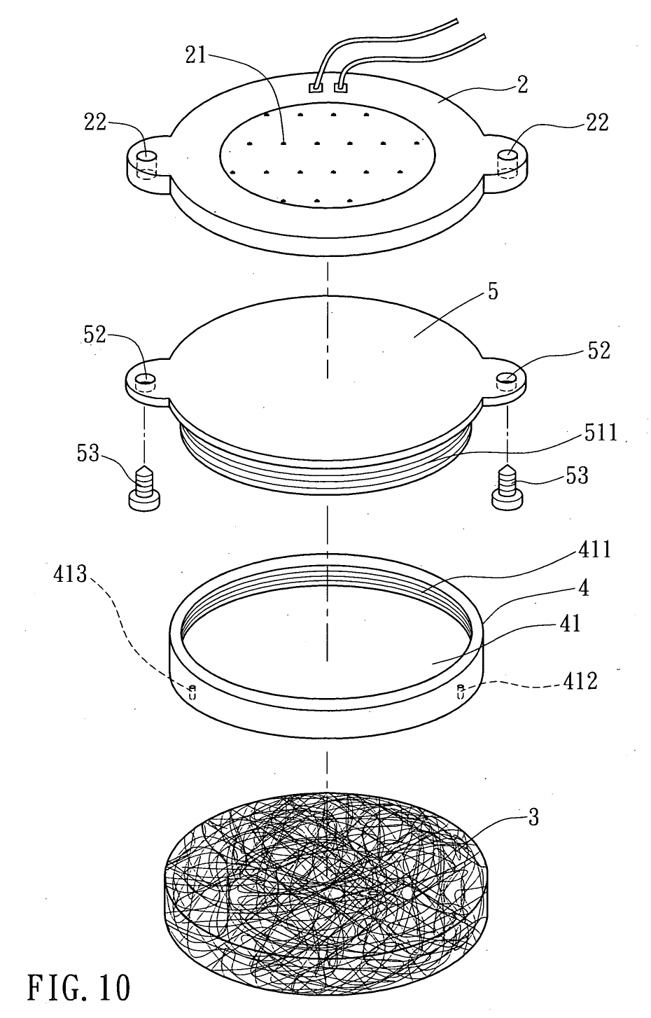

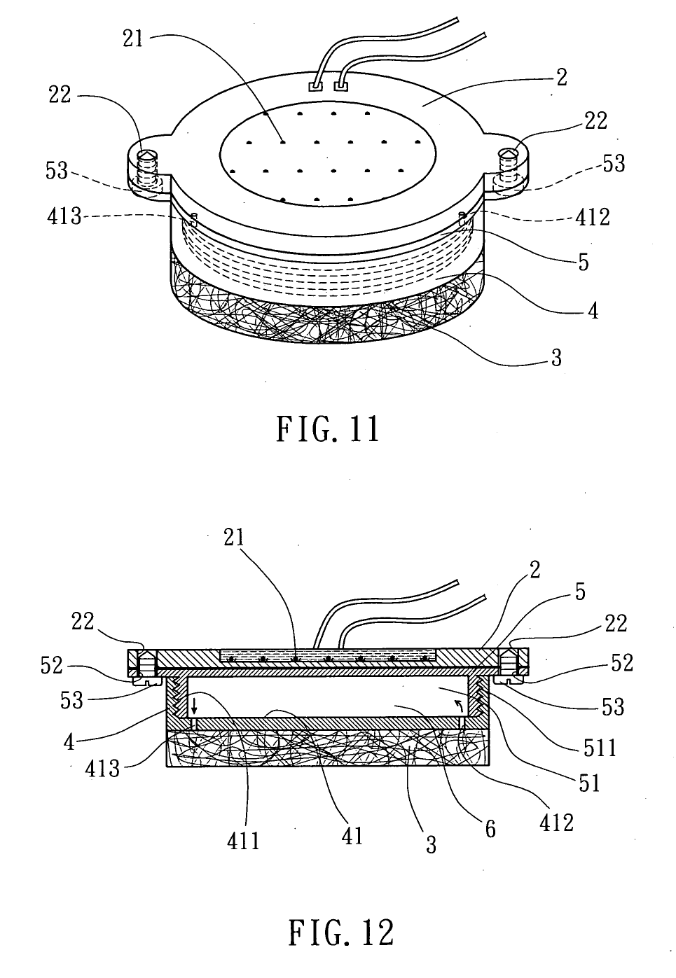

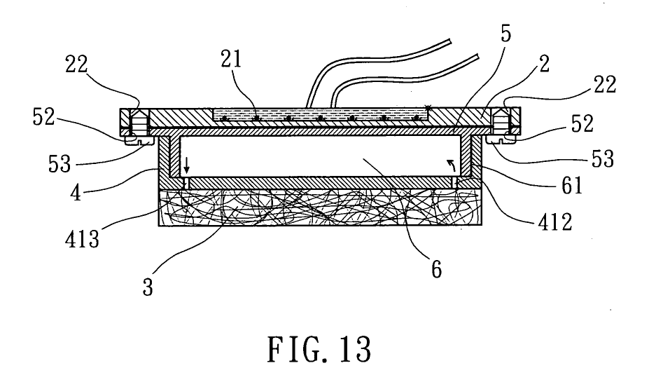

FIGS. 10˜13 show a heat dissipation system in accordance with a fourth embodiment of the present invention. According to this embodiment, the heat dissipation system is comprised of a heat generating electronic device 2, a heat dissipation device 3, a thermal transfer member 4, and a heat conductive cap 5. The heat conductive cap 5 is tightly attached to the bottom surface of the heat generating electronic device 2, defining a bottom open chamber 51 and having two lugs 52 outwardly extending from the border of the flat top wall thereof at two opposing sides and respectively fastened to respective peripheral lugs 22 of the heat generating electronic device 2 with a respective fastening member 53. The heat conductive cap 5 further has an outer thread 511. The thermal transfer member 4 is hollow rounded metal member defining a top open chamber 41 and having an inner thread 411 disposed in the top open chamber 41 and threaded onto the outer thread 511 of the heat conductive cap 5 and two air holes 412 and 413 cut through the bottom wall of the top open chamber 41 at two opposing sides. The heat dissipation device 3 is directly bonded to the bottom surface of the thermal transfer member 4 with a thermal adhesive. Further, a solder paste 61 may be filled in between the inner thread 411 of the thermal transfer member 4 and the outer thread 511 of the heat conductive cap 5 and sealed thereto through a vacuum welding technique. When the heat dissipation system assembled, the top open chamber 41 and the bottom open chamber 51 form an enclosed convection chamber 6.

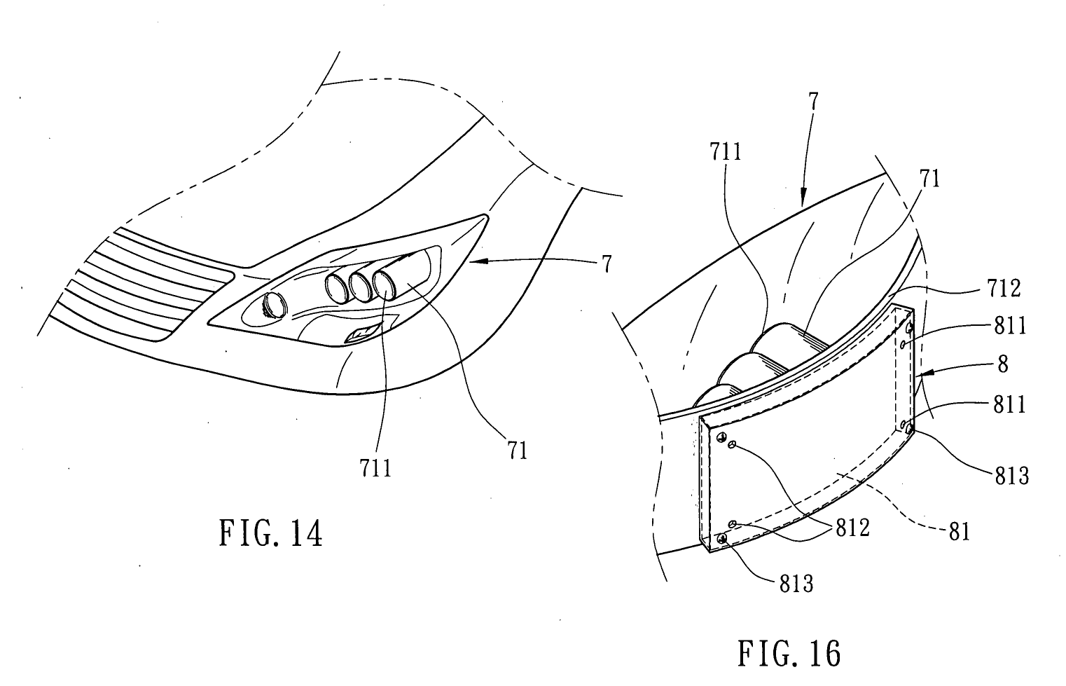

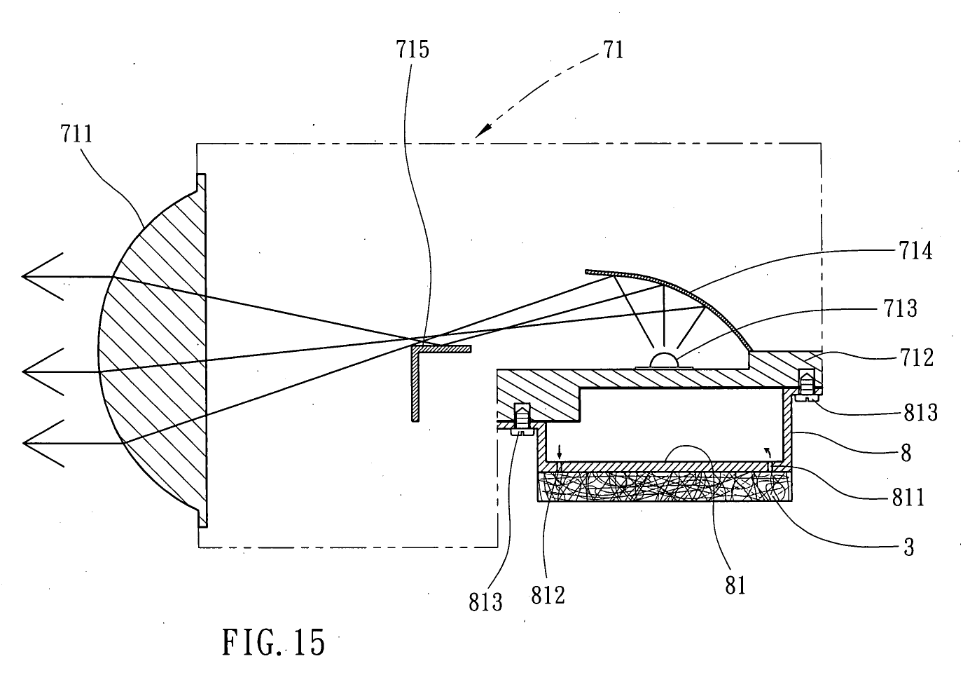

Referring to FIGS. 14 through 16, a vehicle headlamp 7 is shown comprising a light source holder 712 and a plurality of light sources 71 mounted in the light source holder 712. Each light source 71 comprises a LED 713 mounted in the light source holder 712, reflectors 714 and 715, and a lens 711. A heat transfer member 8 is affixed to the back side of the light source holder 712 with screws 813, defining with the light source holder 712 an enclosed convection chamber 81. The heat transfer member 8 has two air holes 811 and 812 cut through the bottom wall thereof for heat convection. A porous heat dissipation device 3 is bonded to the bottom surface of the heat transfer member 8 for quick dissipation of heat energy. The heat transfer member 8 fits the configuration of the light source holder 712. If the light source holder 712 has a curved configuration, the heat transfer member 8 should be relatively curved.

Although particular embodiments of the invention have been described in detail for purposes of illustration, various modifications and enhancements may be made without departing from the spirit and scope of the invention. Accordingly, the invention is not to be limited except as by the appended claims.

What the invention claimed is:

1. A heat dissipation system, comprising:
a heat generating electronic device, said heat generating electronic device comprising two lugs disposed at two opposite lateral sides thereof;
a thermal transfer member made of a metal material having a high efficiency in heat exchange, said thermal transfer member comprising two lugs disposed at two opposing sides thereof and respectively affixed to the lugs of said heat generating electronic device, a top open chamber sealed by said heat generating electronic device to form a convection chamber, and at least one pair of air holes cut through a bottom wall thereof and disposed in communication with said convection chamber; and
a heat dissipation device bonded to the bottom wall of said thermal transfer member, said heat dissipation device having open spaces therein;
wherein when the temperature of the air in said convection chamber rises during operation of said heat generating electronic device, the air pressure in said convection chamber is relatively changed, causing hot air to go out of said convection chamber and outside cold air to go into the inside of said convection chamber through said at least one pair of air holes.

2. The heat dissipation system as claimed in claim 1, further comprising a thermal gasket ring sealed between said heat generating electronic device and said thermal transfer member.

3. The heat dissipation system as claimed in claim 1, wherein said thermal transfer member fits the size and configuration of said heat generating electronic device.

4. The heat dissipation system as claimed in claim 1, wherein said thermal transfer member comprises a bottom extension flange outwardly extending from the periphery of a bottom wall thereof.

5. The heat dissipation system as claimed in claim 1, wherein said thermal transfer member is made of one of power metallurgy, powder sintering and ceramic sintering materials.

6. The heat dissipation system as claimed in claim 1, wherein said heat transfer member comprises multiple pairs of air holes for guiding hot air out of said convection chamber and guiding outside cold air into said convection chamber.

7. A heat dissipation system, comprising:
a heat generating electronic device;
a heat conductive cap tightly attached to a bottom surface of said heat generating electronic device, said heat conductive cap comprising a bottom open chamber and an outer thread;
a thermal transfer member, said thermal transfer member comprising a top open chamber incorporated with said bottom open chamber of said heat conductive cap into a convection chamber, an inner thread threaded onto said outer thread of said heat conductive cap, and at least one pair of air holes cut through a bottom wall thereof for guiding hot air out of said convection chamber and guiding outside cold air into said convection chamber; and
a heat dissipation device bonded to the bottom wall of said thermal transfer member, said heat dissipation device having open spaces therein.

8. The heat dissipation system as claimed in claim 7, wherein said heat generating electronic device comprising two lugs disposed at two opposite lateral sides thereof; said heat conductive cap comprises two lugs outwardly extending disposed at two opposing sides and respectively fastened to the lugs of said heat generating electronic device with a respective fastening member.

9. The heat dissipation system as claimed in claim 7, wherein said thermal transfer member fits the size and configuration of said heat generating electronic device.

10. The heat dissipation system as claimed in claim 7, further comprising a solder paste filled in between the outer thread of said heat conductive cap and said thermal transfer member and sealed thereto through a vacuum welding technique.

11. The heat dissipation system as claimed in claim 7, wherein said heat transfer member comprises multiple pairs of air holes for guiding hot air out of said convection chamber and guiding outside cold air into said convection chamber.

12. A heat dissipation system, comprising:
a vehicle headlamp, said vehicle headlamp comprising a light source holder and a plurality of light sources mounted in a front side of said light source holder, each said light source comprising a light emitting device, reflector means and a lens at a front side of said light emitting device;
a thermal transfer member made of a metal material having a high efficiency in heat exchange, said thermal transfer member comprising a top open chamber sealed by said light source holder of said vehicle headlamp to form a convection chamber, and at least one pair of air holes cut through a bottom wall thereof and disposed in communication with said convection chamber for guiding hot air out of said convection chamber and guiding outside cold air into said convection chamber; and
a heat dissipation device bonded to the bottom wall of said thermal transfer member, said heat dissipation device having open spaces therein.

13. The heat dissipation system as claimed in claim 12, wherein said thermal transfer member fits the size and configuration of said light source holder of said vehicle headlamp.
